(19) United States
(12) Patent Application Publication
(10) Pub. No.: US 2026/0215100 A1
(43) Pub. Date: Jul. 23, 2026

(54) MOTHER SUBSTRATE FOR DISPLAY DEVICE

(71) Applicant: Magnolia White Corporation, Tokyo (JP)

(72) Inventors: Sho YANAGISAWA, Tokyo (JP); Naoya IWAHASHI, Tokyo (JP); Rena KATAOKA, Tokyo (JP); Tomokazu ISHIKAWA, Tokyo (JP)

(73) Assignee: Magnolia White Corporation, Tokyo (JP)

(21) Appl. No.: 19/452,909

(22) Filed: Jan. 20, 2026

(30) Foreign Application Priority Data
Jan. 22, 2025 (JP) 2025-008975

(51) Int. Cl. H10K 59/122; H10K 59/80

(52) U.S. Cl. CPC H10K 59/122; H10K 59/873

(57) ABSTRACT

According to one embodiment, a mother substrate for a display device includes panel portions each including a display area and a surrounding area around the display area, a margin area around the panel portions. The mother substrate includes a lower electrode, a rib layer, a first partition, second partitions, a first stacked film provided including an organic layer of a first color, and a first sealing layer. The second partitions are provided in a layout corresponding to a shape of a process control mark or an alignment mark. Each of the process control mark and the alignment mark is constituted by a first stacked film provided on each of the second partitions and a first sealing layer covering the first stacked film and the second partitions.

### CROSS-REFERENCE TO RELATED APPLICATION

This application is based upon and claims the benefit of priority from Japanese Patent Application No. 2025-008975, filed Jan. 22, 2025, the entire contents of which are incorporated herein by reference.

### FIELD

Embodiments described herein relate generally to a mother substrate for a display device.

### BACKGROUND

Recently, display devices with organic light-emitting diodes (OLED) applied thereto as display elements have been put into practical use. In the manufacturing of such display devices, an inspection is implemented to confirm whether the elements on the substrate are formed as designed. A technique for efficiently and accurately implementing this inspection has been required.

### BRIEF DESCRIPTION OF THE DRAWINGS

FIG. 1 is a view showing a configuration example of a display device according to one embodiment.

FIG. 2 is a schematic plan view showing an example of the layout of subpixels.

FIG. 3 is a schematic cross-sectional view of a display panel along the III-III line of FIG. 2.

FIG. 4 is a schematic plan view of a mother substrate according to one embodiment.

FIG. 5 is a schematic plan view of a part of the mother substrate according to one embodiment.

FIG. 6 is a flowchart showing an example of the manufacturing method of the display device according to one embodiment.

FIG. 7A is a schematic cross-sectional view showing a process of forming a panel portion in the mother substrate according to one embodiment.

FIG. 7B is a schematic cross-sectional view showing a process following the one shown in FIG. 7A.

FIG. 7C is a schematic cross-sectional view showing a process following the one shown in FIG. 7B.

FIG. 7D is a schematic cross-sectional view showing a process following the one shown in FIG. 7C.

FIG. 7E is a schematic cross-sectional view showing a process following the one shown in FIG. 7D.

FIG. 7F is a schematic cross-sectional view showing a process following the one shown in FIG. 7E.

FIG. 7G is a schematic cross-sectional view showing a process following the one shown in FIG. 7F.

FIG. 7H is a schematic cross-sectional view showing a process following the one shown in FIG. 7G.

FIG. 7I is a schematic cross-sectional view showing a process following the one shown in FIG. 7H.

FIG. 7J is a schematic cross-sectional view showing a process following the one shown in FIG. 7I.

FIG. 8 is a schematic plan view showing an example of the configuration applicable to a test pattern according to one embodiment.

FIG. 9 is a schematic cross-sectional view of the mother substrate along the IX-IX line of FIG. 8.

FIG. 10 is a schematic plan view showing an example of the configuration applicable to a test pattern according to one embodiment.

FIG. 11 is a schematic plan view showing a configuration of the test pattern in a state where process control marks and alignment marks are formed in the configuration shown in FIG. 8 and FIG. 9.

FIG. 12 is a schematic plan view showing the area surrounded by the XII line of FIG. 11 in an enlarged manner.

FIG. 13A is a schematic cross-sectional views showing processes of forming elements constituting display elements in the test patterns of the configuration shown in FIG. 8 and FIG. 9.

FIG. 13B is a schematic cross-sectional view showing a process following the one shown in FIG. 13A.

FIG. 13C is a schematic cross-sectional view showing a process following the process shown in FIG. 13B.

FIG. 13D is a schematic cross-sectional view showing a process following the one shown in FIG. 13C.

FIG. 14 is a schematic plan view showing an example of the configuration applicable to a test pattern according to one embodiment.

FIG. 15 is a schematic cross-sectional view of the mother substrate along the XV-XV line of FIG. 14.

FIG. 16 is a schematic plan view showing a configuration of the test pattern in a state where process control marks and alignment marks are formed in the configuration shown in FIG. 14 and FIG. 15.

FIG. 17 is a schematic plan view showing the area surrounded by the XVII line of FIG. 16 in an enlarged manner.

FIG. 18A is a schematic cross-sectional views showing processes of forming elements constituting display elements in the test patterns of the configuration shown in FIG. 14 and FIG. 15.

FIG. 18B is a schematic cross-sectional view showing a process following the one shown in FIG. 18A.

FIG. 18C is a schematic cross-sectional view showing a process following the one shown in FIG. 18B.

FIG. 18D is a schematic cross-sectional view showing a process following the one shown in FIG. 18C.

FIG. 19 is a schematic plan view showing an example of the configuration applicable to a test pattern according to one embodiment.

FIG. 20A is a schematic cross-sectional view showing an example of the configuration of a test pattern according to a comparative example.

FIG. 20B is a schematic cross-sectional view showing an example of the configuration applicable to a test pattern according to one embodiment.

### DETAILED DESCRIPTION

In general, according to one embodiment, a mother substrate for a display device includes a plurality of panel portions each including a display area and a surrounding area around the display area, a margin area around the plurality of panel portions, a lower electrode provided in the display area, a rib layer provided in the plurality of panel portions and the margin area, a first partition provided in the display area, a plurality of second partitions provided in the margin area, a first stacked film provided in the plurality of panel portions and the margin area and including an organic layer of a first color, and a first sealing layer covering the first stacked film. The plurality of second partitions are provided in a layout corresponding to a shape of a process control mark or an alignment mark. Each of the process control mark and the alignment mark is constituted by a first stacked film provided on each of the plurality of second partitions and a first sealing layer covering the first stacked film and the plurality of second partitions.

According to another embodiment, a mother substrate for a display device includes a plurality of panel portions each including a display area and a surrounding area around the display area, a margin area around the plurality of panel portions, a lower electrode provided in the display area, a rib layer provided in the plurality of panel portions and the margin area, a first partition provided in the display area, a second partition provided in the margin area, a first stacked film provided in the plurality of panel portions and the margin area and including an organic layer of a first color, and a first sealing layer covering the first stacked film. The second partition has outer shapes corresponding to a shape of a process control mark or an alignment mark and has a plurality of partition apertures. Each of the process control mark and the alignment mark is constituted by a first stacked film provided on each of the plurality of partition apertures and a first sealing layer provided to cover the plurality of partition apertures.

According to still another embodiment, a mother substrate for a display device includes a plurality of panel portions each including a display area and a surrounding area surrounding the display area, a margin area around the plurality of panel portions, a lower electrode provided in the display area, a rib layer provided in the plurality of panel portions and the margin area, a first partition provided in the display area, a second partition provided in the margin area, a first stacked film provided in the plurality of panel portions and the margin area and including an organic layer of a first color, a first sealing layer covering the first stacked film, and a first resin layer covering the first sealing layer. The second partition has a plurality of partition apertures. Each of the plurality of partition apertures has a width of 40 μm or more.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. Z-direction is a normal to the plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

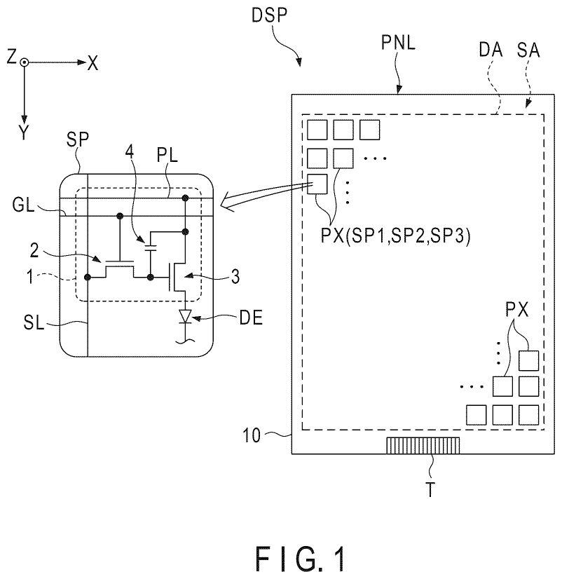

FIG. 1 is a view showing a configuration example of a display device DSP according to one embodiment. The display device DSP comprises a display panel PNL including an insulating substrate 10. The display panel PNL has a display area DA for displaying images and a surrounding area SA around the display area DA. The substrate 10 may be glass or a resinous film having flexibility.

In the present embodiment, the substrate 10 has a rectangular shape in plan view. The shape of the substrate 10 in plan view is not limited to the rectangular shape and may be another shape such as a square shape, a circular shape, or an elliptic shape.

The display area DA comprises a plurality of pixels PX arranged in a matrix in the X-direction and the Y-direction. Each pixel PX includes a plurality of subpixels SP displaying different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL supplying a scanning signal to the pixel circuit 1 of each subpixel SP, a plurality of signal lines SL supplying a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

A gate electrode of the pixel switch 2 is connected to the scanning line GL. One of a source electrode and a drain electrode of the pixel switch 2 is connected to the signal line SL. The other is connected to a gate electrode of the drive transistor 3 and the capacitor 4. In the drive transistor 3, one of a source electrode and a drain electrode is connected to the power line PL and the capacitor 4. The other is connected to the display element DE.

The configuration of the pixel circuit 1 is not limited to the example of the figure. For example, the pixel circuit 1 may comprise more thin-film transistors and capacitors.

The display device DSP further comprises a terminal portion T provided in the surrounding area SA. For example, a flexible printed circuit board is connected to the terminal portion T. Signals and voltages for driving the pixel circuit 1 are input to the display device DSP through this flexible circuit board and the terminal portion T.

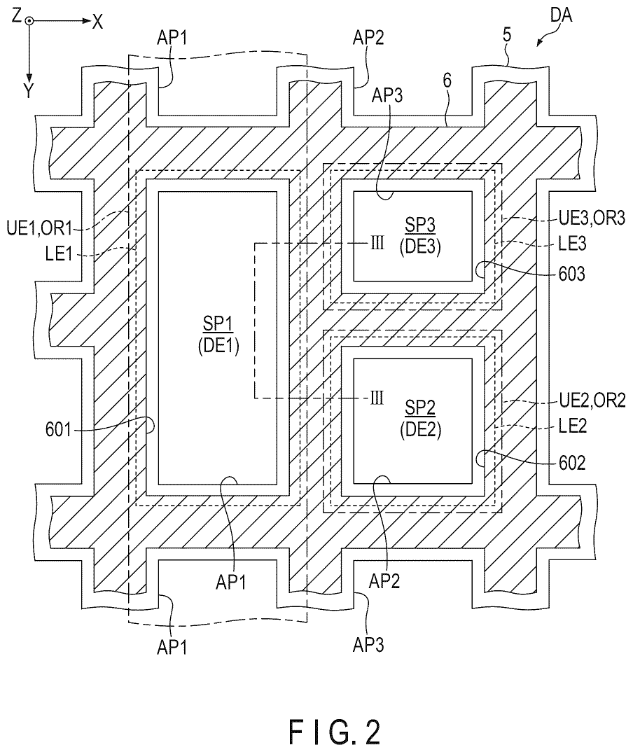

FIG. 2 is a schematic plan view showing an example of the layout of the subpixels SP1, SP2, and SP3. In the example of FIG. 2, the subpixels SP2 and SP3 are arranged with the subpixel SP1 in the X-direction. Further, the subpixels SP2 and SP3 are arranged in the Y-direction.

When the subpixels SP1, SP2, and SP3 are arranged in this layout, in the display area DA, a column in which the subpixels SP2 and SP3 are alternately arranged in the Y-direction and a column in which the plurality of subpixels SP1 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, the pixel aperture AP1 is greater than the pixel aperture AP2, and the pixel aperture AP2 is greater than the pixel aperture AP3. Thus, among the subpixels SP1, SP2, and SP3, the aperture ratio of the subpixel SP1 is the greatest, and the aperture ratio of the subpixel SP3 is the least.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 (the first partition) is provided above the rib layer 5. The partition 6 functions as lines applying common voltage to the upper electrodes UE1, UE2, and UE3. The partition 6 entirely overlaps the rib layer 5 and has the same planar shape as the rib layer 5.

More specifically, the partition 6 has a partition aperture 601 in the subpixel SP1, a partition aperture 602 in the subpixel SP2, and a partition aperture 603 in the subpixel SP3. The partition apertures 601, 602, and 603 are greater than the respective pixel apertures AP1, AP2, and AP3. The partition apertures 601, 602, and 603 overlap the whole of the respective display elements DE1, DE2, and DE3. That is, the partition 6 surrounds the display elements DE1, DE2, and DE3.

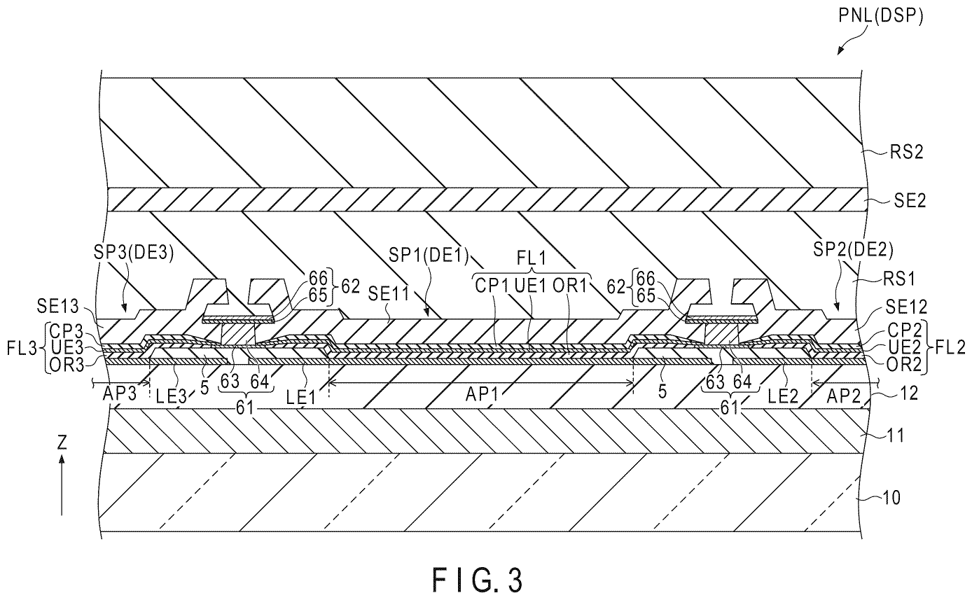

FIG. 3 is a schematic cross-sectional view of the display panel PNL along the III-III line of FIG. 2. A circuit layer 11 is provided on the substrate 10 described above. The circuit layer 11 includes various circuits and lines such as the pixel circuit 1, the scanning line GL, the signal line SL, and the power lines PL shown in FIG. 1. The circuit layer 11 is covered with an organic insulating layer 12. The organic insulating layer 12 functions as a planarization film planarizing irregularities formed by the circuit layer 11.

Each of the lower electrodes LE1, LE2, and LE3 is provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. This configuration causes both end portions of the upper portion 62 to protrude relative to the side surfaces of the lower portion 61. This shape of the partition 6 is called an overhang shape.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, both end portions of the bottom layer 63 protrude relative to the side surfaces of the stem layer 64.

Further, in the example of FIG. 3, the upper portion 62 comprises a first top layer 65 and a second top layer 66 provided on the first top layer 65. For example, the width of the second top layer 66 is slightly smaller than the width of the first top layer 65. The configuration is not limited to this, and the first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13 are provided in the respective subpixels SP1, SP2, and SP3. The sealing layer SE11 continuously covers the stacked film FL1 and the subpixel SP1 and the partition 6 around them. The sealing layer SE12 continuously covers the stacked film FL2 and the subpixel SP2 and the partition 6 around them. The sealing layer SE13 continuously covers the stacked film FL3 and the subpixel SP3 and the partition 6 around them.

In the example of FIG. 3, the sealing layer SE11 located on the partition 6 between the subpixels SP1 and SP2 is spaced apart from the sealing layer SE12 located on this partition 6. The sealing layer SE11 located on the partition 6 between the subpixels SP1 and SP3 is spaced apart from the sealing layer SE13 located on this partition 6. In another example, an end portion of the sealing layer SE11 and an end portion of the sealing layer SE12 may overlap each other on the partition 6. Similarly, an end portion of the sealing layer SE11 and an end portion of the sealing layer SE13 may overlap each other on the partition 6.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed, for example, of silver and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. For example, each of the organic layers OR1, OR2, and OR3 has a structure in which a hole injection layer, a hole transport layer, an electron blocking layer, a light emitting layer, a hole blocking layer, an electron transport layer, and an electron injection layer are stacked in this order in the Z-direction. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 63 and the stem layer 64 of the lower portion 61 of the partition 6 is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material. Further, the lower portion 61 may be formed of a single layer.

For example, the first top layer 65 of the partition 6 is formed of a metal material. Further, the second top layer 66 of the partition 6 is formed, for example, of a conductive oxide material. For the metal material forming the first top layer 65, for example, titanium, a titanium nitride, molybdenum, tungsten, a molybdenum-tungsten alloy, or a molybdenum-niobium alloy may be used. For a conductive oxide forming the second top layer 66, for example, an ITO or an IZO may be used. The upper portion 62 may comprise three or more layers. Alternatively, the upper portion 62 may be formed of a single layer. The upper portion 62 may further include a layer formed of an insulating material.

Common voltage is applied to the partition 6. This common voltage is applied to each of the upper electrodes UE1, UE2, and UE3 contacting the lower portions 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light in the blue wavelength range. When a potential difference is formed between the lower electrode LE2 and the upper electrode UE2, the light emitting layer of the organic layer OR2 emits light in the green wavelength range. When a potential difference is formed between the lower electrode LE3 and the upper electrode UE3, the light emitting layer of the organic layer OR3 emits light in a red wavelength range.

In another example, the light emitting layers of the organic layers OR1, OR2, and OR3 may emit light of the same color (for example, white). In this case, the display device DSP may comprise a color filter that converts light emitted from the light emitting layers into light of the colors corresponding to those of the subpixels SP1, SP2, and SP3. Further, the display device DSP may comprise a layer including quantum dots that are excited by light emitted from the light emitting layers to generate light of the colors corresponding to those of the subpixels SP1, SP2, and SP3.

In the manufacturing of the display device DSP, a large mother substrate is fabricated, the mother substrate comprising a plurality of areas (panel portions) each corresponding to the display panel PNL. The following will describe a configuration applicable to this mother substrate.

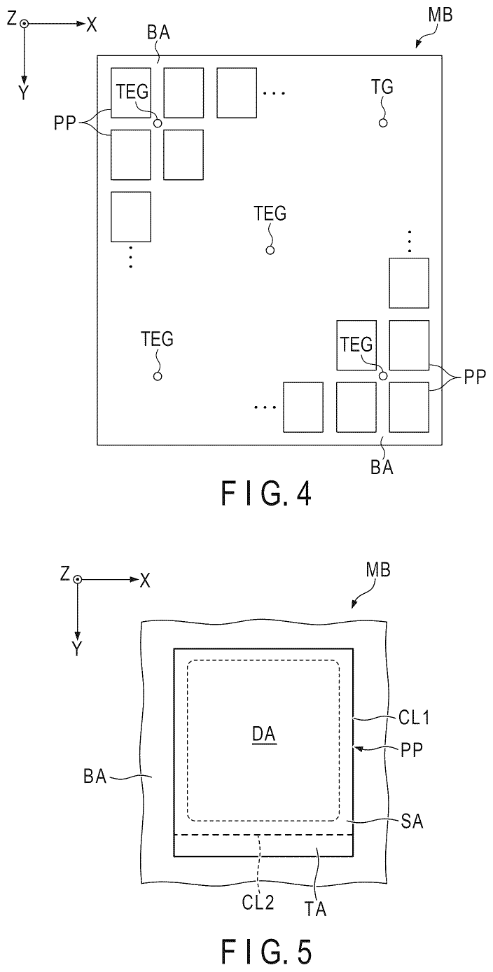

FIG. 4 is a schematic plan view of a mother substrate MB (a mother substrate for a display device) according to the present embodiment. For example, the mother substrate MB has a rectangular shape as shown in the figure. However, the mother substrate MB may have another shape such as a circular shape.

The mother substrate MB comprises a plurality of panel portions PP arranged in a matrix and a margin area BA around these panel portions PP. In the example of FIG. 4, the panel portions PP are arranged in the X-direction and the Y-direction via the margin area BA. However, at least two of the panel portions PP provided in the mother substrate MB may be adjacent to each other without intervention of the margin area BA.

The mother substrate MB further comprises at least one test pattern TEG. In the example of FIG. 4, a plurality of test patterns TEG are provided in the margin area BA. Positions and number of these test patterns TEG are not particularly limited. In one example, the test patterns TEG are preferably distributed at various positions such as in the vicinity of the end portion of the mother substrate MB and near a center of the mother substrate MB.

FIG. 5 is a schematic plan view of a part of the mother substrate MB. This figure focuses attention on one panel portion PP. The outer shape of the panel portion PP corresponds to a cut line CL1 for cutting out the panel portion PP from the mother substrate MB.

Each panel portion PP has the display area DA and the surrounding area SA. Further, the surrounding area SA includes an inspection area TA. In the inspection area TA, an inspection pad for inspecting the operation of the display panel PNL and the like are provided.

In each panel portion PP, a cut line CL2 is formed. This cut line CL2 divides the panel portions PP into a part including the display area DA and a part including the inspection area TA.

In the manufacturing of the display device DSP, the panel portion PP is first cut out from the mother substrate MB along the cut line CL1. Further, this cut-out panel portion PP is subjected to the inspection using the inspection pad. After this inspection, the inspection area TA is cut out from the panel portion PP along the cut line CL2.

The test pattern TEG shown in FIG. 4 is provided in the surrounding area SA as well as the margin area BA. For example, the test pattern TEG can be provided in the inspection area TA. In this case, the test pattern TEG does not remain in the panel portion PP in which the inspection area TA has been cut out along the cut line CL2. Even when the test pattern TEG is provided in the margin area BA as shown in FIG. 4, the test pattern TEG does not remain in the panel portion PP after the inspection area TA is separated along the cut line CL2.

In another example, the test pattern TEG may be provided in a part excluding the inspection area TA of the surrounding area SA. In this case, the test pattern TEG remains in the panel portion PP in which the inspection area TA has been cut out along the cut line CL2.

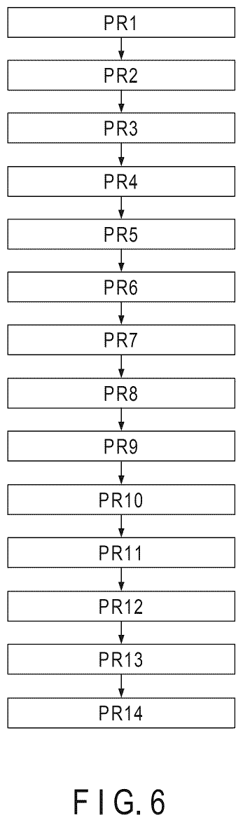

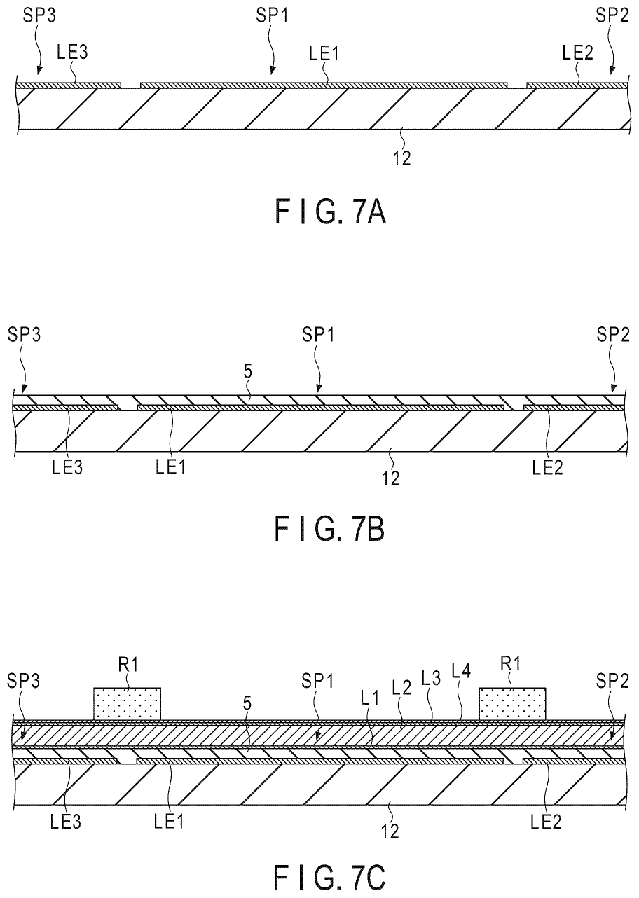

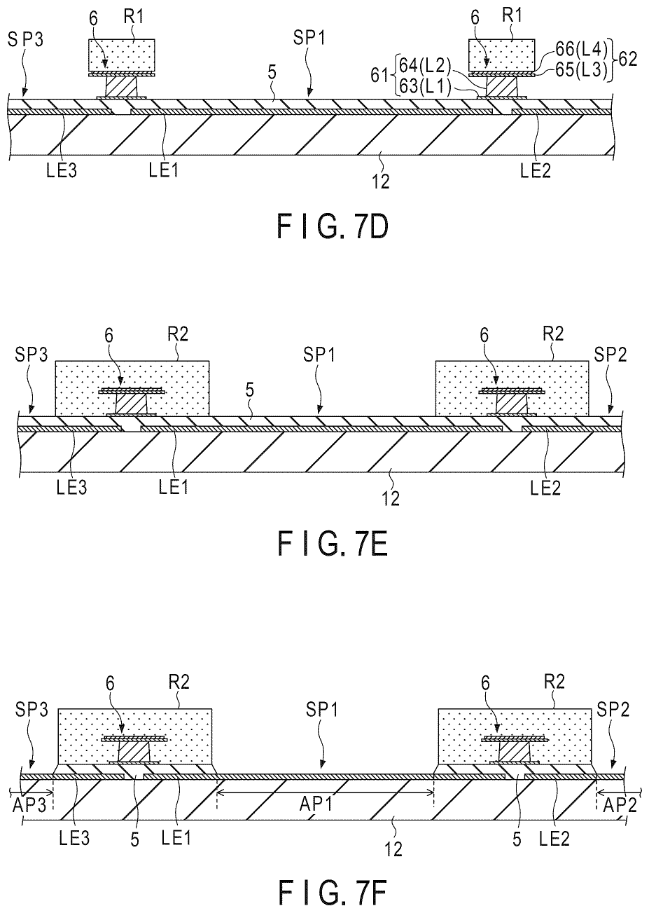

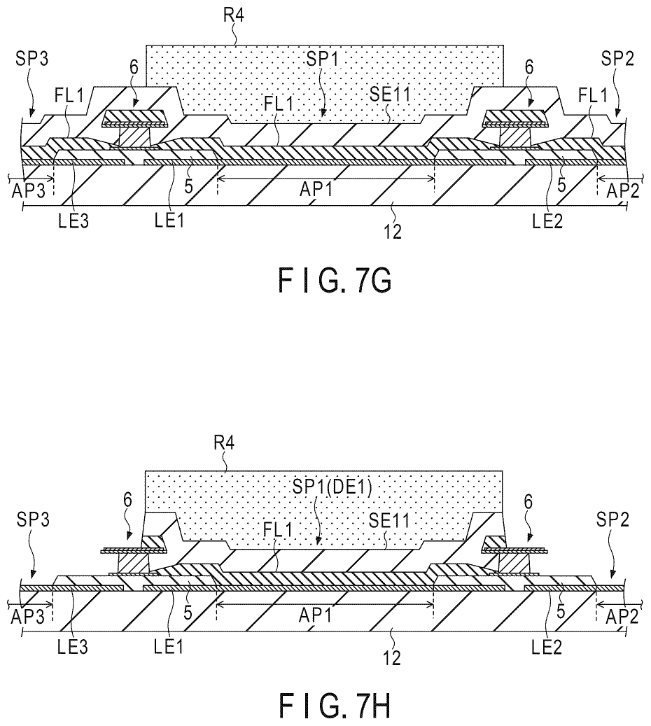

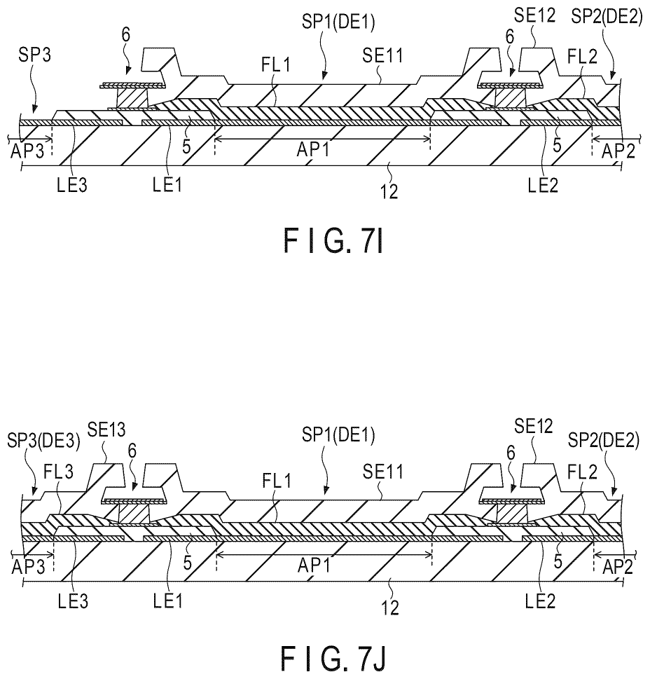

The following will describe an example of the manufacturing method of the display device DSP. FIG. 6 is a flowchart showing an example of the manufacturing method of the display device DSP. FIG. 7A to FIG. 7J are schematic cross-sectional views showing manufacturing processes of the panel portions PP on the mother substrate MB. FIG. 7A to FIG. 7J mainly focus on the display area DA and omit the illustration of elements under the organic insulating layer 12.

In the formation of the panel portions PP, first, the circuit layer 11 and the organic insulating layer 12 are formed on the substrate 10 of the mother substrate MB (the process PR1 in FIG. 6). Next, as shown in FIG. 7A, the lower electrodes LE1, LE2, and LE3 are formed on the organic insulating layer 12 (the process PR2 in FIG. 6).

Subsequently, as shown in FIG. 7B, the rib layer 5 covering the lower electrodes LE1, LE2, and LE3 is formed on the entire mother substrate MB (the process PR3 in FIG. 6). At this time, the pixel apertures AP1, AP2, and AP3 are not provided in the rib layer 5. The rib layer 5 can be formed by chemical vapor deposition (CVD).

After the formation of the rib layer 5, processes for forming the partition 6 are performed (the processes PR4 and PR5 in FIG. 6). In the process PR4, as shown in FIG. 7C, a first layer L1 to be processed into the bottom layer 63, a second layer L2 to be processed into the stem layer 64, a third layer L3 to be processed into the first top layer 65, and a fourth layer L4 to be processed into the second top layer 66 are sequentially formed over the entire mother substrate MB. Further, a resist R1 is provided on the fourth layer L4. The resist R1 is patterned into the shape of the partition 6. The first layer L1, the second layer L2, the third layer L3, and the fourth layer L4 can be formed by sputtering, for example.

In the subsequent process PR5, the first layer L1, the second layer L2, the third layer L3, and the fourth layer L4 are patterned using the resist R1 as a mask. In one example, the first layer L1 is formed of a titanium nitride, the second layer L2 is formed of aluminum, the third layer L3 is formed of titanium, and the fourth layer L4 is formed of an ITO. In this case, the process PR5 may include wet etching for removing the portion exposed from the resist R1 of the fourth layer L4, dry etching for removing the portions exposed from the resist R1 of the first layer L1, the second layer L2, and the third layer L3, and wet etching for reducing the width of the second layer L2. Types of etching performed in the process PR5 are selected as appropriate according to the structure and materials of the partition 6.

The process PR5 completes the formation of the partition 6 in the display area DA as shown in FIG. 7D. After the formation of the partition 6, the resist R1 is removed (stripped). During the wet etching that reduces the width of the second layer L2, the second top layer 66 (the fourth layer L4) may also be slightly corroded. When this corrosion occurs, the width of the second top layer 66 becomes smaller than the width of the first top layer 65.

Next, the process for providing the pixel apertures AP1, AP2, and AP3 is performed (the process PR6 in FIG. 6). In the process PR6, a resist R2 covering the partition 6 is formed as shown in FIG. 7E. Further, dry etching for the rib layer 5 is performed using the resist R2 as a mask. Thus, as shown in FIG. 7F, the pixel apertures AP1, AP2, and AP3 are formed in the rib layer 5. The respective lower electrodes LE1, LE2, and LE3 are exposed from the pixel apertures AP1, AP2, and AP3. After these dry etching processes, the resist R2 is removed (stripped).

After the process PR6, a process for removing the rib layer 5 in the terminal portion T shown in FIG. 1 is performed (the process PR7 in FIG. 6).

After the process PR7, the process for forming the display element DE1 is performed (the process PR8 in FIG. 6). As shown in FIG. 7G, in the formation of the display element DE1, the stacked film FL1 and the sealing layer SE11 are formed first. As shown in FIG. 3, the stacked film FL1 includes the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed not in only the display area DA of each panel portion PP but also on the entire mother substrate MB including the surrounding area SA and the margin area BA. The partition 6 having an overhang shape divides the stacked film FL1 into a plurality of parts. The sealing layer SE11 continuously covers these parts, into which the stacked film FL1 has been divided, and the partition 6.

Subsequently, the stacked film FL1 and the sealing layer SE11 are patterned. As shown in FIG. 7G, a resist R3 is provided on the sealing layer SE11 in this patterning. The resist R3 covers the subpixel SP1 and a part of the partition 6 around the subpixel SP1.

Thereafter, the etching process using the resist R3 as a mask is performed. As shown in FIG. 7H, parts exposed from the resist R3 of the stacked film FL1 and the sealing layer SE11 are removed. That is, parts overlapping the lower electrode LE1 of the stacked film FL1 and the sealing layer SE11 remain. The other parts are removed. Thus, the display element DE1 is formed in the subpixel SP1. For example, in the surrounding area SA and the margin area BA, the stacked film FL1 and the sealing layer SE11 are removed by the etching process. This etching process may include wet etching and dry etching performed in order for the sealing layer SE11, the cap layer CP1, the upper electrode UE1, and the organic layer OR1. After these etching processes, the resist R3 is removed (stripped).

After the process PR8, the process for forming the display element DE2 is performed (the process PR9 in FIG. 6). The display element DE2 can be formed by the same procedure as that of the display element DE1. That is, in the formation of the display element DE2, the stacked film FL2 and the sealing layer SE12 are formed on the entire mother substrate MB. As shown in FIG. 3, the stacked film FL2 includes the organic layer OR2 contacting the lower electrode LE2 through the pixel aperture AP2, the upper electrode UE2 covering the organic layer OR2, and the cap layer CP2 covering the upper electrode UE2.

The organic layer OR2, the upper electrode UE2, and the cap layer CP2 may be formed by, for example, vapor deposition. The sealing layer SE12 may be formed by, for example, CVD. The partition 6 having an overhang shape divides the stacked film FL2 into a plurality of parts. The sealing layer SE12 continuously covers these parts, into which the stacked film FL2 has been divided, and the partition 6. Patterning these stacked film FL2 and sealing layer SE12 forms the display element DE2 in the subpixel SP2 as shown in FIG. 7I. For example, in the surrounding area SA and the margin area BA, the stacked film FL2 and the sealing layer SE12 are removed by the etching process of this patterning.

After the process PR9, the process for forming the display element DE3 is performed (the process PR10 in FIG. 6). The display element DE3 can be formed by the same procedures as those of the display elements DE1 and DE2. That is, in the formation of the display element DE3, the stacked film FL3 and the sealing layer SE13 are formed on the entire mother substrate MB. As shown in FIG. 3, the stacked film FL3 includes the organic layer OR3 contacting the lower electrode LE3 through the pixel aperture AP3, the upper electrode UE3 covering the organic layer OR3, and the cap layer CP3 covering the upper electrode UE3.

The organic layer OR3, the upper electrode UE3, and the cap layer CP3 may be formed by, for example, vapor deposition. The sealing layer SE13 may be formed by, for example, CVD. The partition 6 having an overhang shape divides the stacked film FL3 into a plurality of parts. The sealing layer SE13 continuously covers these parts, into which the stacked film FL3 has been divided, and the partition 6. As shown in FIG. 7J, patterning these stacked film FL3 and sealing layer SE13 forms the display element DE3 in the subpixel SP3. For example, the etching in this patterning removes the stacked film FL3 and the sealing layer SE13 in the surrounding area SA and the margin area BA.

Here, the above description assumes that the display elements DE1, DE2, and DE3 are formed in this order. However, the display elements DE1, DE2, and DE3 may be formed in another order.

After the formations of the display elements DE1, DE2, and DE3, the resin layer RS1, the sealing layer SE2, and the resin layer RS2 shown in FIG. 3 are sequentially formed (the process PR11 in FIG. 6). Further, each panel portion PP is cut out from the mother substrate MB along the cut line CL1 (the process PR12 in FIG. 6).

Thereafter, each panel portion PP undergoes inspection (the process PR13 in FIG. 6). This inspection includes illumination inspection of the display elements DE1, DE2, and DE3 using the inspection pad provided in the inspection area TA and the like. After this inspection, the inspection area TA is cut out along the cut line CL2 (the process PR14 in FIG. 6). This completes the display panel PNL.

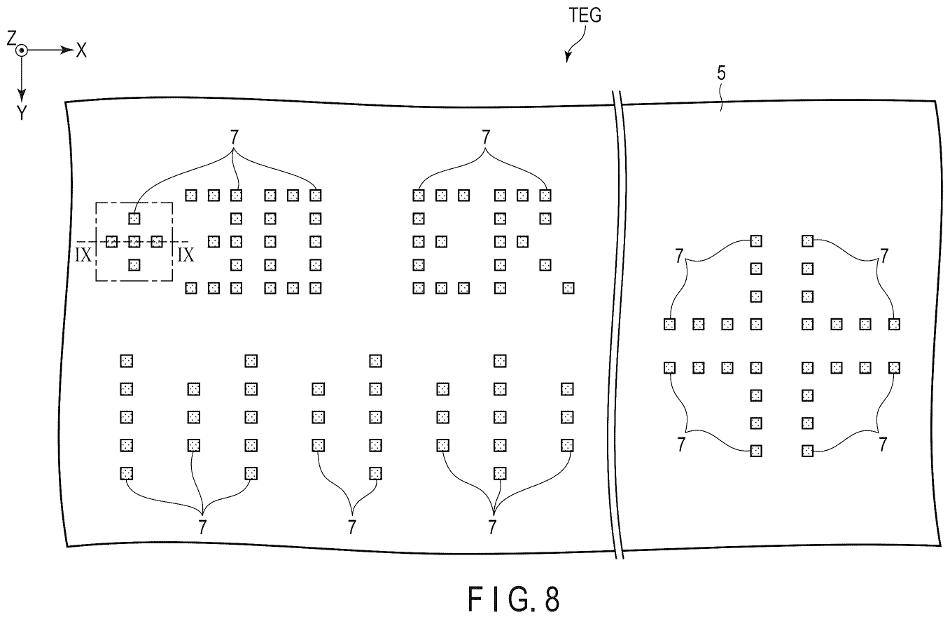

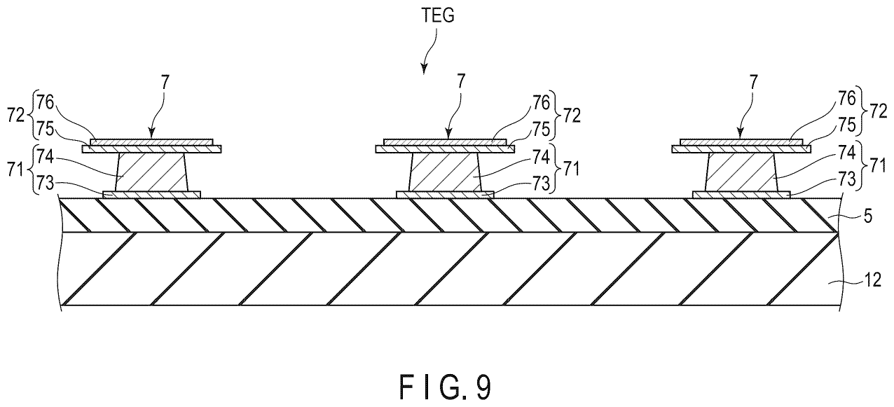

FIG. 8 is a schematic plan view showing an example of a configuration applicable to the test pattern TEG. FIG. 9 is a schematic cross-sectional view of the mother substrate MB including the test pattern TEG along the IX-IX line of FIG. 8. FIG. 9 omits the illustration of elements below the organic insulating layer 12.

The configuration shown in FIG. 8 and FIG. 9 is applicable to the test pattern TEG on which at least one of verniers for checking a position of an exposure mask, identification characters for checking whether elements constituting the display elements are normally formed, and alignment marks used for aligning various elements is formed. Verniers and identification characters serve as marks used to control whether various processes for manufacturing the display panel PNL are normally performed. Thus, the verniers and identification character may be referred to as process control marks.

As shown in FIG. 8, the test pattern TEG is constituted by the rib layer 5 and a plurality of partitions 7 (the second partition and the protrusion portions).

The rib layer 5 is provided across the panel portions PP and the margin area BA shown in FIG. 4.

The plurality of partitions 7 are provided on the rib layer 5 in the layout corresponding to the shape of the process control mark and in the layout corresponding to the shape of the alignment mark. In the example of FIG. 8, the plurality of partitions 7 are provided on the rib layer 5 in the layouts corresponding to the shapes of bar-shaped verniers extending longer in the Y-direction, an identification character “+30”, an identification character “ER”, and L-shaped alignment marks. This configuration will be described in detail later.

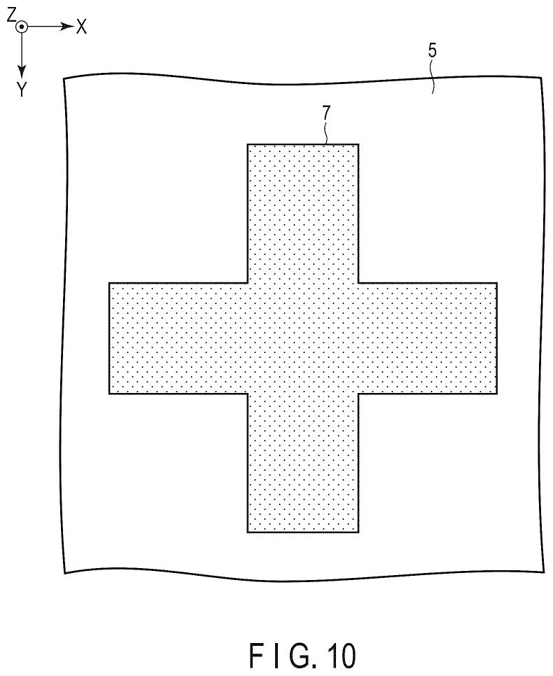

FIG. 8 shows as an example the configuration in which a total of five partitions 7 are provided in the X-direction and in the Y-direction as the partitions 7 that correspond to a “+” part of the identification character “+30” (see the area surrounded by one-dot chain lines in the figure). Alternatively, for example, a single cross-shaped partition 7 may be provided as the partition 7 that corresponds to the “+” part as shown in FIG. 10. A partition 7 that has a large size may cause electrostatic discharge (ESD) or result in formation failure of the process control marks (for example, a stacked film that constitutes the process control mark may be stripped). In view of these points, the configuration of FIG. 8 has more preferable layout of the partitions 7 corresponding to the “+” part than that of the configuration of FIG. 10.

FIG. 8 shows as an example the configuration in which each partition 7 has a square shape in plan view. The shape of the partition 7 is not limited to this example and may be another shape such as a rectangular shape in plan view.

In the same manner as the partition 6, as shown in FIG. 9, the partition 7 includes a lower portion 71 (a bottom layer 73 and a stem layer 74) and an upper portion 72 (a first top layer 75 and a second top layer 76). Further, in the same manner as the partition 6, the partition 7 is also configured such that both end portions of the bottom layer 73 protrude relative to side surfaces of the stem layer 74.

The lower portion 71 of the partition 7 is formed of the same material as the lower portion 61 of the partition 6. More specifically, the bottom layer 73 and the stem layer 74 are respectively formed of the same materials as the bottom layer 63 and the stem layer 64 of the partition 6. The thickness of the bottom layer 73 is equivalent to the thickness of the bottom layer 63 of the partition 6. Further, the thickness of the stem layer 74 is equivalent to the thickness of the stem layer 64 of the partition 6.

The upper portion 72 of the partition 7 is formed of the same material as the upper portion 62 of the partition 6. More specifically, the first top layer 75 and the second top layer 76 are respectively formed of the same materials as the first top layer 65 and the second top layer 66 of the partition 6. The thickness of the first top layer 75 is equivalent to the thickness of the first top layer 65 of the partition 6. The thickness of the second top layer 76 is equivalent to the thickness of the second top layer 66 of the partition 6.

The partition 7 is formed by the same processes PR4 and PR5 in FIG. 6 as the partition 6. That is, in the processes PR4 and PR5, the bottom layers 73 are formed on the rib layers 5, the stem layers 74 are formed on the bottom layers 73, the first top layers 75 are formed on the stem layers 74, and the second top layers 76 are formed on the first thin films 75.

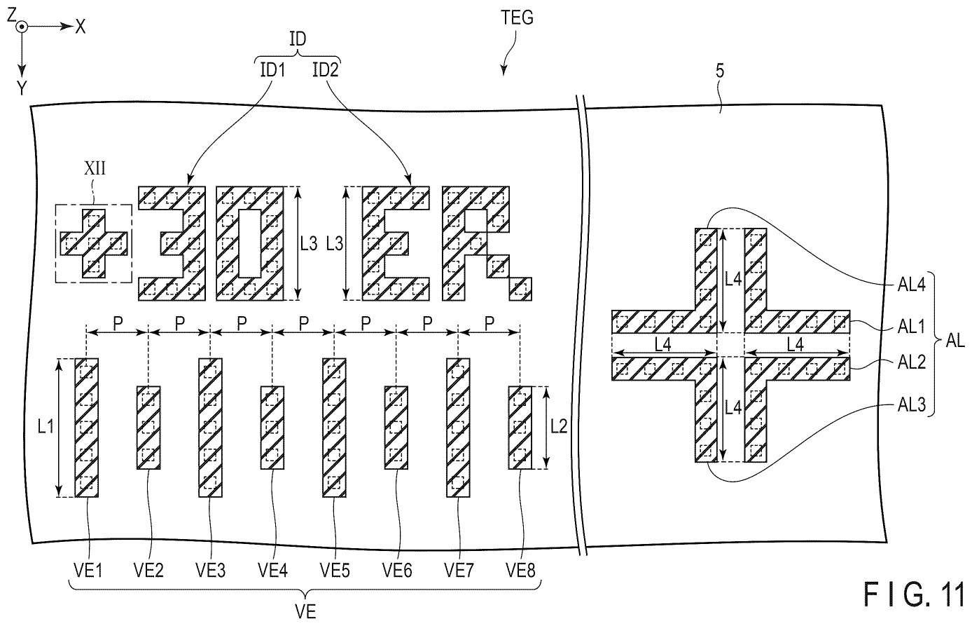

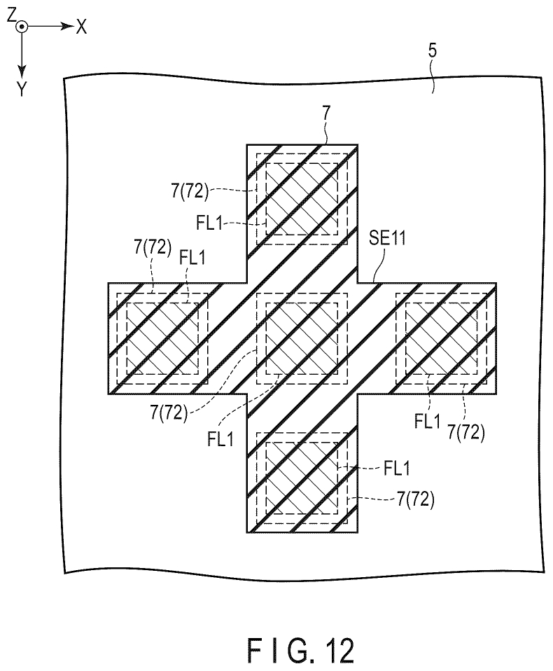

FIG. 11 is a schematic plan view showing a configuration of the test pattern TEG in a state where process control marks and alignment marks are formed in the configuration shown in FIG. 8 and FIG. 9. FIG. 11 shows as an example the configuration where the test pattern TEG includes the process control marks and the alignment marks formed during the process of forming the display element DE1 in the display area DA (that is, in the process PR8 in FIG. 6). FIG. 12 is a schematic plan view showing the area surrounded by the XII line of FIG. 11 in an enlarged manner.

In the example of FIG. 11, the test pattern TEG has a plurality of verniers VE and a plurality of identification characters ID as process control marks. The test pattern TEG further has a plurality of alignment marks AL in addition to the process control marks described above.

FIG. 12 shows only a part of the identification characters ID surrounded by the XII line of FIG. 11 in an enlarged manner. The verniers VE, the identification characters ID, and the alignment marks AL all have similar structures and are constituted by the stacked film FL1 and the sealing layer SE11. The stacked film FL1 constituting the verniers VE, the identification characters ID, and the alignment marks AL is provided on the upper portion 72 of the partitions 7 provided on the rib layer 5 and is not provided at other positions. The sealing layer SE11 constituting the verniers VE, the identification characters ID, and the alignment marks AL is provided to cover the partitions 7 provided on the rib layer 5 and the stacked film FL1 provided on the upper portion 72 of the partitions 7.

In the example of FIG. 11, the plurality of verniers VE include verniers VE1 to VE8. The verniers VE1 to VE8 extend in the Y-direction and are formed in a rectangular shape extending longer in the Y-direction.

In the example of FIG. 11, the verniers VE1 to VE8 have the same width in the X-direction. This example assumes that the number of verniers is eight. Alternatively, the number of verniers may be seven or fewer or nine or more.

The verniers VE1 to VE8 are arranged in the X-direction at equal pitch. More specifically, respective pitches P of the verniers VE1 to VE8 are equivalent to each other.

In the example of FIG. 11, the verniers VE1, VE3, VE5, and VE7 have the same length in the Y-direction, and the verniers VE2, VE4, VE6, and VE8 have the same length in the Y-direction. The length in the Y-direction of the verniers VE1, VE3, VE5, and VE7 is defined as a length L1 and the length in the Y-direction of the verniers VE2, VE4, VE6, and VE8 is defined as the length L2. The length L1 is larger than the length L2 (L1>L2). The relationship of the lengths of the verniers VE1 to VE8 in the Y-direction is not limited to this example. For example, all of the verniers VE1 to VE8 have the same length in the Y-direction. That is, the length L1 may be equivalent to the length L2 (L1=L2).

In the example of FIG. 11, the plurality of identification characters ID include identification characters ID1 and ID2. The identification character ID1 has a shape corresponding to a numeral “+30”. The identification character ID2 has a shape corresponding to letters “ER”. The identification characters ID1 and ID2 are arranged in the X-direction with a predetermined interval.

The identification characters ID1 and ID2 have the same length in the Y-direction. FIG. 11 shows an example where each of the identification characters ID1 and ID2 has a length L3 in the Y-direction, which is equivalent to the length L1 of the verniers VE1, VE3, VE5, and VE7. The identification characters ID1 and ID2 do not necessarily have the same length in the Y-direction and may have substantially equal (similar) lengths. The identification characters ID and verniers VE do not necessarily have the same length in the Y-direction and may have mutually different lengths.

In the example of FIG. 11, the plurality of alignment marks AL include alignment marks AL1 to AL4. The alignment mark AL1 has an L shape. The alignment mark AL2 has a shape obtained by rotating the alignment mark AL1 rightward (clockwise) by 90 degrees. The alignment mark AL3 has a shape obtained by rotating the alignment mark AL2 rightward (clockwise) by 90 degrees. The alignment mark AL4 has a shape obtained by rotating the alignment mark AL3 rightward (clockwise) by 90 degrees.

In the example of FIG. 11, the alignment marks AL1 to AL4 have the same length in the X-direction. Further, the alignment marks AL1 to AL4 have the same length in the Y-direction. FIG. 11 shows an example where the alignment marks AL1 to AL4 have a length L4 in both of the X-direction and the Y-direction. That is, FIG. 11 shows the case where the length in the X-direction and the length in the Y-direction are equivalent to each other. The alignment marks AL1 to AL4 do not necessarily have the same length in the X-direction and the Y-direction. The length in the X-direction of the alignment marks AL1 to AL4 may differ from the length in the Y-direction of the alignment marks AL1 to AL4.

FIG. 11 and FIG. 12 shows the test pattern TEG formed at a predetermined position in the margin area BA and including the process control marks and the alignment marks formed in the process PR8. At another position in the margin area BA, another test pattern TEG including the process control marks and the alignment marks formed during the process of forming the display element DE2 in the display area DA (that is, in the process PR9 in FIG. 6) and constituted by the stacked film FL2 and the sealing layer SE12 is formed in the same manner as the test pattern TEG shown in FIG. 11 and FIG. 12. At still another position in the margin area BA, another test pattern TEG including the process control marks and the alignment marks formed during the process of forming the display element DE3 in the display area DA (that is, in the process PR10 in FIG. 6) and constituted by the stacked film FL3 and the sealing layer SE13 is formed in the same manner as the test pattern TEG shown in FIG. 11 and FIG. 12.

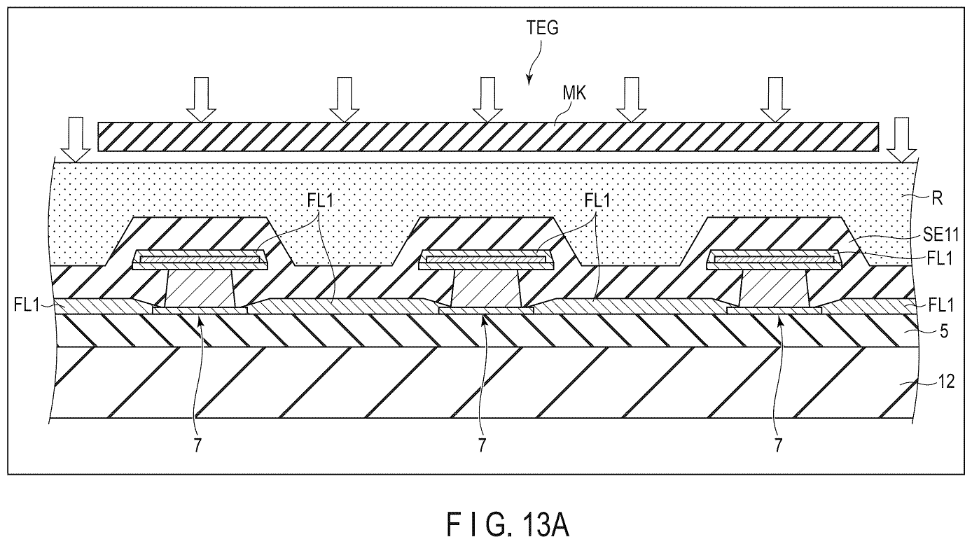

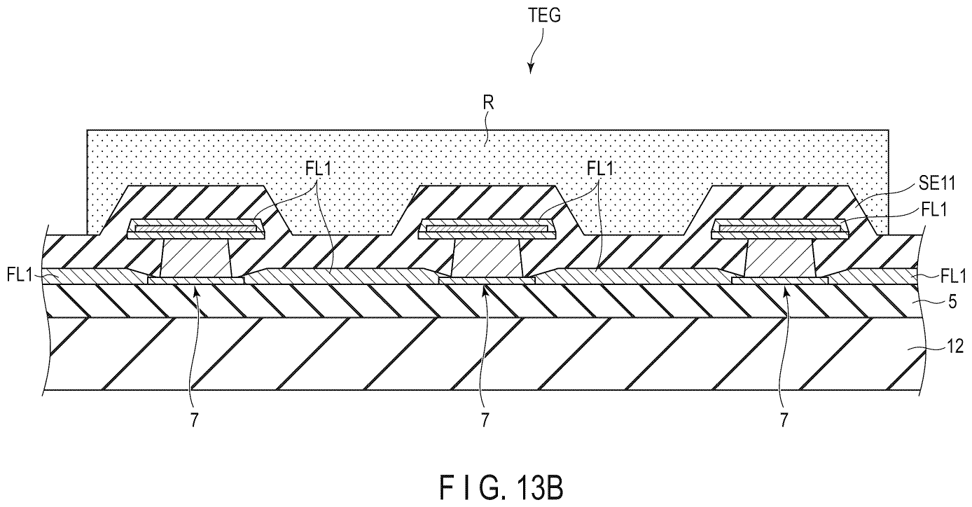

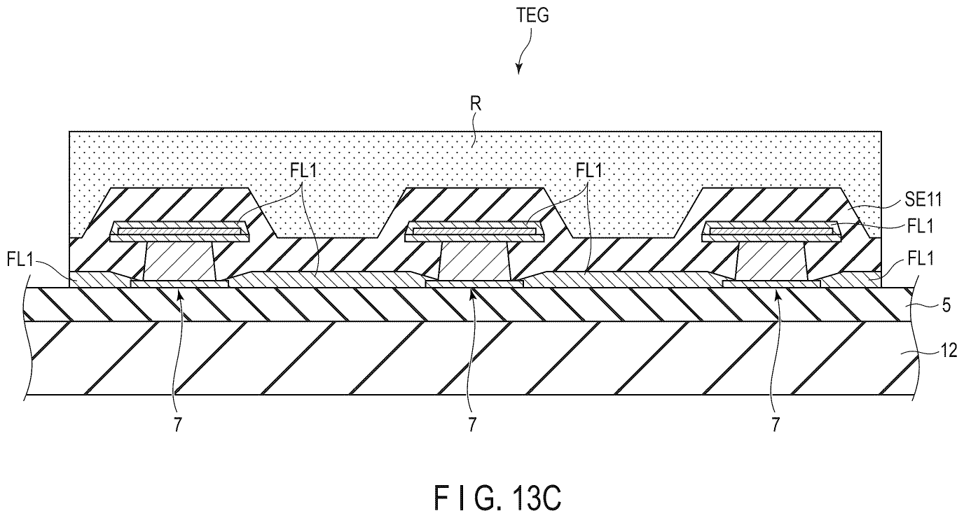

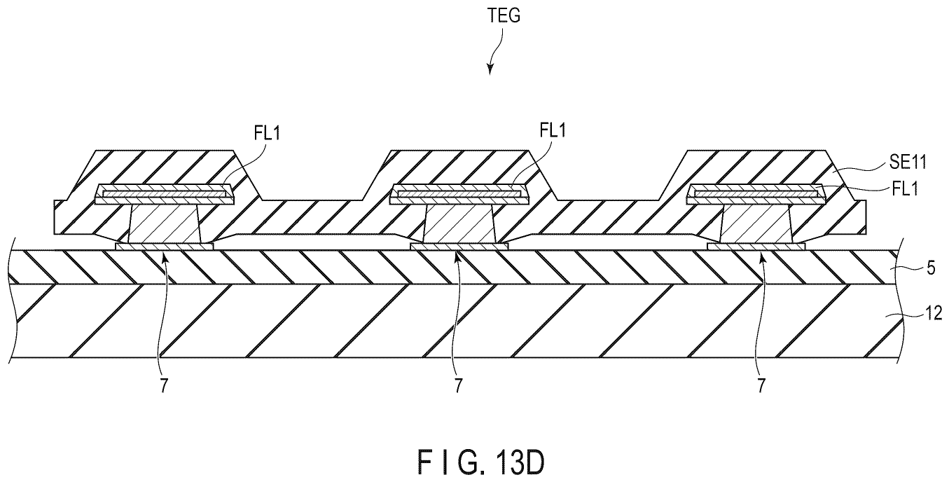

FIG. 13A to FIG. 13D are schematic cross-sectional views showing cases where the process PR8 for forming the display element DE1 is performed on the test pattern TEG of the configuration shown in FIG. 8 and FIG. 9. These cross-sectional views of FIG. 13A to FIG. 13D show the cross section of the same part as the one shown in FIG. 9 and omit the illustration of the components below the organic insulating layer 12.

In the process PR8, the stacked film FL1 and the sealing layer SE11 are formed on the rib layer 5 and the partitions 7 as shown in FIG. 13A. A resist R corresponding to the resist R3 shown in FIG. 7H is formed on the stacked film FL1 and the sealing layer SE11. Further, the resist R is exposed to light using the mask MK as shown by several arrows. The mask MK has a shape corresponding to the process control marks and the alignment marks formed on the test pattern TEG. In other words, the mask MK has apertures at positions other than the positions where the process control marks and the alignment marks are formed. The resist R is, for example, a positive resist. Thus, parts exposed to light of the resist R is removed by a development process as shown in FIG. 13B.

Thereafter, the etching process using the resist R as a mask is performed. As shown in FIG. 13C, this process removes parts exposed from the resist R of the stacked film FL1 and the sealing layer SE11. The stacked film FL1 and the sealing layer SE11 that constitute the process control marks and the alignment marks are covered with the resist R and are therefore not removed in this etching process. The sealing layer SE11 provided around the partitions 7 adheres strongly to the partitions 7 (the side surfaces of the partitions 7) and is not stripped with the resist R in the removal (stripping) of the resist R following this process. Accordingly, as shown in FIG. 13D, the sealing layer SE11 provided around the partitions 7 and the stacked film FL1 provided on the partitions 7 remain in the test pattern TEG after the removal of the resist R. These sealing layer SE11 and stacked film FL1 function as the process control marks and the alignment marks. The stacked film FL1 provided in the vicinity of the side surfaces of the partitions 7 is removed by interfacial etching by a stripping solution used to strip the resist R or by subsequent etching processes.

The above describes the case where the process PR8 for forming the display element DE1 is performed on the test pattern TEG of the configuration shown in FIG. 8 and FIG. 9. In a case where the process PR9 for forming the display element DE2 is performed on the test pattern TEG of the configuration shown in FIG. 8 and FIG. 9 as well, the sealing layer SE12 provided around the partitions 7 and the stacked film FL2 provided on the partitions 7 similarly remain and function as the process control marks and the alignment marks. Similarly, in a case where the process PR10 for forming the display element DE3 is performed on the test pattern TEG of the configuration shown in FIG. 8 and FIG. 9 as well, the sealing layer SE13 provided around the partitions 7 and the stacked film FL3 provided on the partitions 7 similarly remain and function as the process control marks and the alignment marks.

As described above, placement of the plurality of partitions 7 in the margin area BA in the layout corresponding to the process control marks and the alignment marks to be formed as the test pattern TEG enables formation, in the margin area BA, of the test pattern TEG that includes the process control marks and the alignment marks constituted by the stacked films FL1, FL2, and FL3 and the sealing layers SE11, SE12, and SE13.

The formation of the test pattern TEG including the process control marks and the alignment marks in the margin area BA enables, for example, checking whether an exposure mask has been placed at a correct position during the manufacturing processes of the display panel PNL by using a vernier that is one of the process control marks. Formation of the test pattern TEG including the process control marks and the alignment marks in the margin area BA further enables, for example, checking whether elements constituting the display elements are normally formed by using identification characters that are one of the process control marks. Furthermore, formation of the test pattern TEG including the process control marks and the alignment marks in the margin area BA enables, for example, alignment of various elements by using the alignment marks.

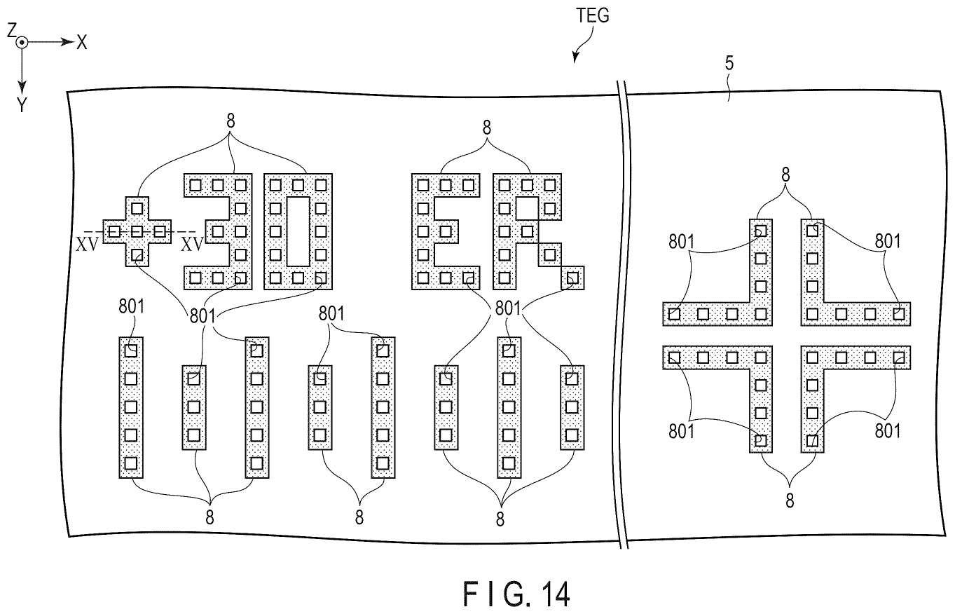

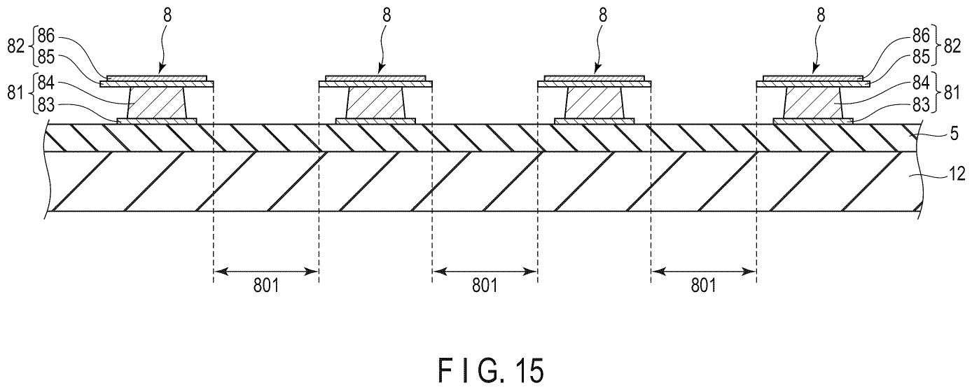

FIG. 14 is a schematic plan view showing another example of the configuration applicable to the test pattern TEG. FIG. 15 is a schematic cross-sectional view of the mother substrate MB including the test pattern TEG along the XV-XV line of FIG. 14. FIG. 15 omits the illustration of elements below the organic insulating layer 12. In the same manner as the configuration shown in FIG. 8 and FIG. 9, the configuration shown in FIG. 14 and FIG. 15 is applicable to the test pattern TEG on which the process control marks and the alignment marks are formed.

As shown in FIG. 14, the test pattern TEG is constituted by the rib layer 5 and a plurality of partitions 8 (the second partitions).

The rib layer 5 is provided across the panel portions PP and the margin area BA shown in FIG. 4.

Outer shapes of the plurality of partitions 8 correspond to the shapes of the respective process control marks and alignment marks. In the example of FIG. 14, the partitions 8 that have the outer shapes corresponding to the bar-shaped verniers extending longer in the Y-direction, the partitions 8 that have the outer shapes corresponding to the identification character “+30”, the partitions 8 that have the outer shapes corresponding to the identification character “ER”, and the partitions 8 that have the outer shapes corresponding to the L-shaped alignment marks are provided on the rib layer 5.

Each partition 8 has a plurality of partition apertures 801 (recessed portions). The number of the partition apertures 801 formed in each partition 8 and shapes and sizes of the partition apertures 801 can be selected arbitrarily. In view of normal formation of the process control marks and the alignment marks, formation of a large number of small partition apertures 801 is preferable. Formation of a large number of small partition apertures 801 advantageously increases contact area between the partition 8 and the sealing layers SE11, SE12, and SE13.

In the same manner as the partition 6, as shown in FIG. 15, the partition 8 includes a lower portion 81 (a bottom layer 83 and a stem layer 84) and an upper portion 82 (a first top layer 85 and a second top layer 86). Further, in the same manner as the partition 6, the partition 8 is also configured such that both end portions of the bottom layer 83 protrude relative to side surfaces of the stem layer 84.

The lower portion 81 of the partition 8 is formed of the same material as the lower portion 61 of the partition 6. More specifically, the bottom layer 83 and the stem layer 84 are respectively formed of the same materials as the bottom layer 63 and the stem layer 64 of the partition 6. The thickness of the bottom layer 83 is equivalent to the thickness of the bottom layer 63 of the partition 6. Further, the thickness of the stem layer 84 is equivalent to the thickness of the stem layer 64 of the partition 6.

The upper portion 82 of the partition 8 is formed of the same material as the upper portion 62 of the partition 6. More specifically, the first top layer 85 and the second top layer 86 are respectively formed of the same materials as the first top layer 65 and the second top layer 66 of the partition 6. The thickness of the first top layer 85 is equivalent to the thickness of the first top layer 65 of the partition 6. The thickness of the second top layer 86 is equivalent to the thickness of the second top layer 66 of the partition 6.

The partition 8 is formed by the same processes PR4 and PR5 in FIG. 6 as the partition 6. That is, in the processes PR4 and PR5, the bottom layers 83 are formed on the rib layers 5, the stem layers 84 are formed on the bottom layers 83, the first top layers 85 are formed on the stem layers 84, and the second top layers 86 are formed on the first thin films 85. Thereafter, the plurality of partition apertures 801 including three partition apertures 801 shown in FIG. 15 are formed.

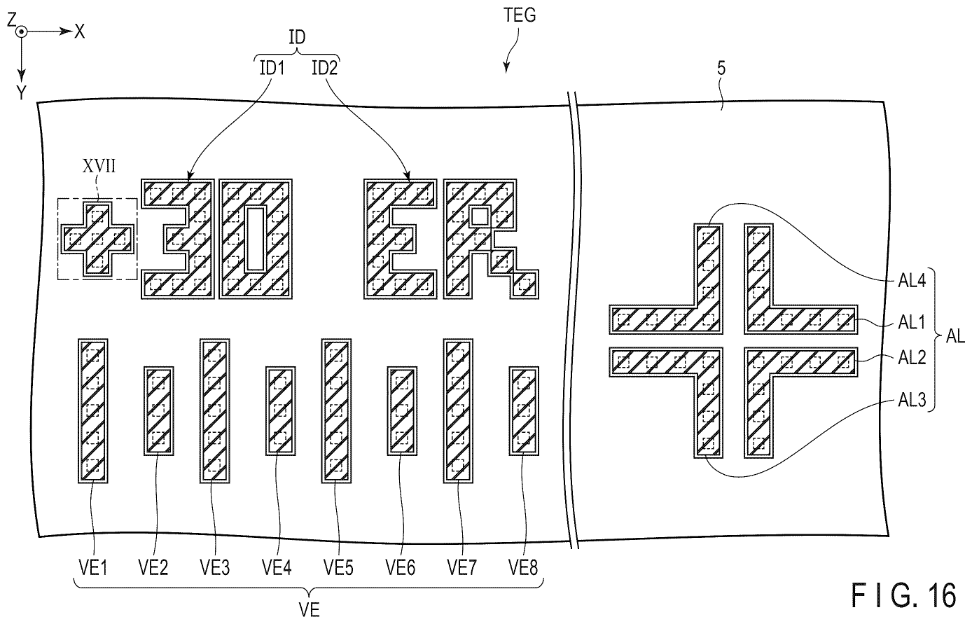

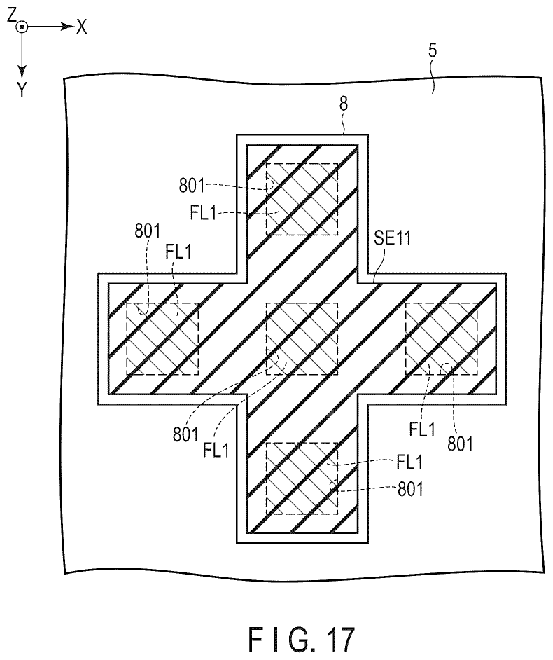

FIG. 16 is a schematic plan view showing a configuration of the test pattern TEG in a state where process control marks and alignment marks are formed in the configuration shown in FIG. 14 and FIG. 15. FIG. 15 shows as an example the configuration where the test pattern TEG includes the process control marks and the alignment marks formed during the process of forming the display element DE1 in the display area DA (that is, in the process PR8 in FIG. 6). FIG. 17 is a schematic plan view showing the area surrounded by the XVII line of FIG. 16 in an enlarged manner.

In the example of FIG. 16, the test pattern TEG has the verniers VE1 to VE8 and the identification characters ID1 and ID2 as the process control marks. The test pattern TEG further has the alignment marks AL1 to AL4 in addition to the process control marks described above.

FIG. 17 shows only a part of the identification characters ID1 surrounded by the XVII line of FIG. 16 in an enlarged manner. The verniers VE1 to VE8, the identification characters ID1 and ID2, and the alignment marks AL1 to AL4 all have similar structures and are constituted by the stacked film FL1 and the sealing layer SE11. The stacked film FL1 constituting the verniers VE1 to VE8, the identification characters ID1 and ID2, and the alignment marks AL1 to AL4 is provided on the rib layer 5 in the partition aperture 801 and is not provided at other positions. The sealing layer SE11 constituting the verniers VE1 to VE8, the identification characters ID1 and ID2, and the alignment marks AL1 to AL4 covers the partition aperture 801. More specifically, the sealing layer SE11 constituting the verniers VE1 to VE8, the identification characters ID1 and ID2, and the alignment marks AL1 to AL4 continuously covers the stacked film FL1 provided on the partition aperture 801 and a part of the upper portion 82 of the partition 8.

Shapes and sizes (lengths) of the verniers VE1 to VE8, the identification characters ID1 and ID2, and the alignment marks AL1 to AL4 are similar to those in the example of FIG. 11 Thus, the following will omit their detailed descriptions.

FIG. 16 and FIG. 17 shows the test pattern TEG formed at a predetermined position in the margin area BA and including the process control marks and the alignment marks formed in the process PR8. At another position in the margin area BA, another test pattern TEG including the process control marks and the alignment marks formed during the process of forming the display element DE2 in the display area DA (that is, in the process PR9 in FIG. 6) and constituted by the stacked film FL2 and the sealing layer SE12 is formed in the same manner as the test pattern TEG shown in FIG. 16 and FIG. 17. At still another position in the margin area BA, another test pattern TEG including the process control marks and the alignment marks formed during the process of forming the display element DE3 in the display area DA (that is, in the process PR10 in FIG. 6) and constituted by the stacked film FL3 and the sealing layer SE13 is formed in the same manner as the test pattern TEG shown in FIG. 16 and FIG. 17.

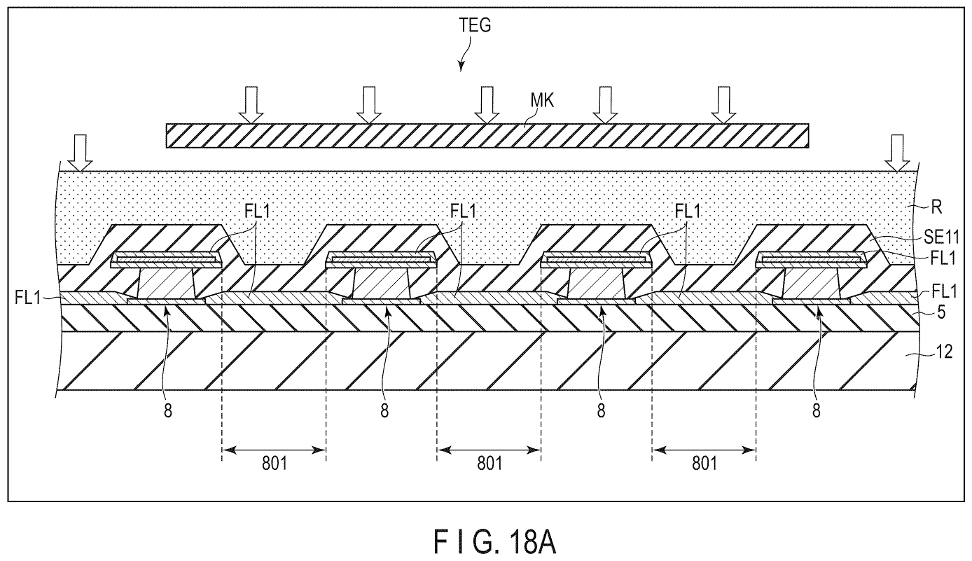

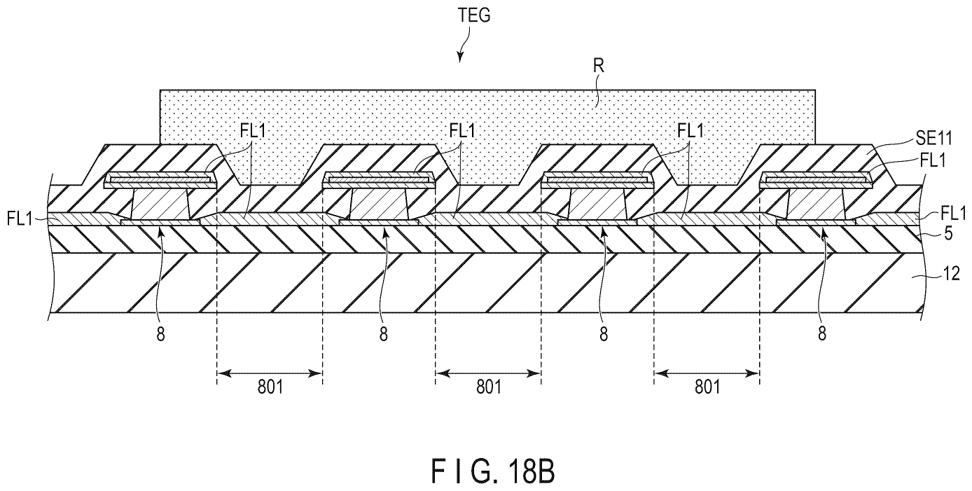

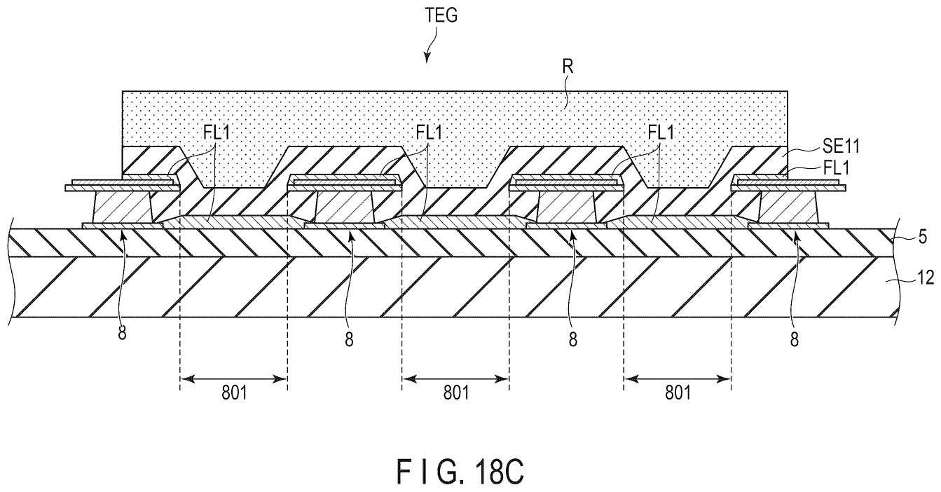

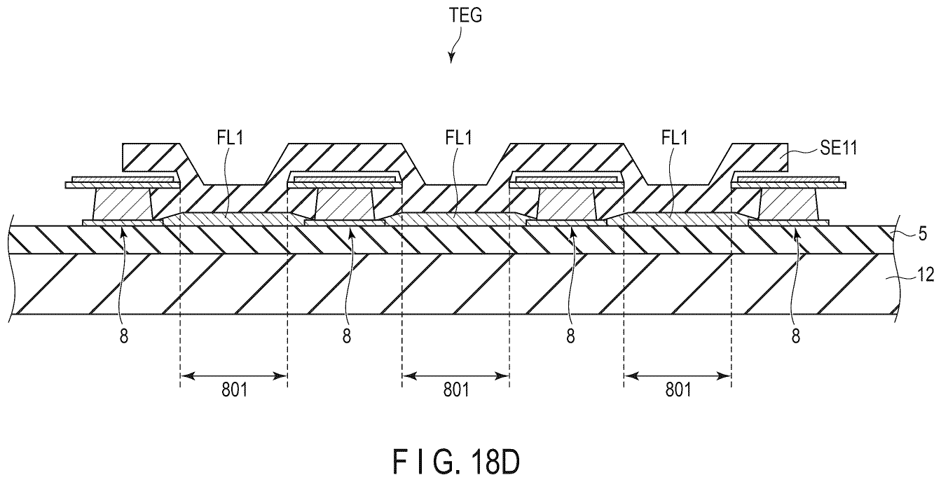

FIG. 18A to FIG. 18D are schematic cross-sectional views showing cases where the process PR8 for forming the display element DE1 is performed on the test pattern TEG of the configuration shown in FIG. 14 and FIG. 15. These cross-sectional views of FIG. 18A to FIG. 18D show the cross section of the same part as the one shown in FIG. 15 and omit the illustration of the components below the organic insulating layer 12.

In the process PR8, the stacked film FL1 and the sealing layer SE11 are formed on the rib layer 5 and the partitions 8 as shown in FIG. 18A. The resist R corresponding to the resist R3 shown in FIG. 7H is formed on the stacked film FL1 and the sealing layer SE11. Further, the resist R is exposed to light using the mask MK as shown by several arrows. The mask MK has a shape corresponding to the process control marks and the alignment marks formed on the test pattern TEG. In other words, the mask MK has apertures at positions other than the positions where the process control marks and the alignment marks are formed. The resist R is, for example, a positive resist. Thus, parts exposed to light of the resist R is removed by a development process as shown in FIG. 18B.

Thereafter, the etching process using the resist R as a mask is performed. As shown in FIG. 18C, this process removes parts exposed from the resist R of the stacked film FL1 and the sealing layer SE11. The stacked film FL1 and the sealing layer SE11 that constitute the process control marks and the alignment marks are covered with the resist R and are therefore not removed in this etching process. The sealing layer SE11 provided around the partitions 8 and the partition apertures 801 adheres strongly to the partitions 8 (the side surfaces of the partitions 8) and is not stripped with the resist R in the removal (stripping) of the resist following this process. Accordingly, as shown in FIG. 18D, the stacked film FL1 provided around the partition aperture 801 and the sealing layer SE11 provided on the partition aperture 801 and the upper portion 82 therearound remain in the test pattern TEG after the removal of the resist R and function as the process control marks and the alignment marks. The stacked film FL1 provided on the upper portion 82 of the partitions 8 is removed by interfacial etching by a stripping solution used to strip the resist R or by subsequent etching processes.

The above describes the case where the process PR8 for forming the display element DE1 is performed on the test pattern TEG of the configuration shown in FIG. 14 and FIG. 15. In a case where the process PR9 for forming the display element DE2 is performed on the test pattern TEG of the configuration shown in FIG. 14 and FIG. 15 as well, the stacked film FL2 provided in the partition aperture 801 and the sealing layer SE12 provided in the partition aperture 801 and the upper portion 82 therearound remain similarly and function as the process control marks and the alignment marks. In a case where the process PR10 for forming the display element DE3 is performed on the test pattern TEG of the configuration shown in FIG. 14 and FIG. 15 as well, the stacked film FL3 provided in the partition aperture 801 and the sealing layer SE13 provided in the partition aperture 801 and the upper portion 82 therearound remain similarly and function as the process control marks and the alignment marks.

As described above, placement in the margin area BA of the plurality of partitions 8 that has the outer shape corresponding to the process control marks and the alignment marks to be formed as the test pattern TEG and having the partition apertures 801 enables formation, in the margin area BA, of the test pattern TEG that includes the process control marks and the alignment marks constituted by the stacked films FL1, FL2, and FL3 and the sealing layers SE11, SE12, and SE13.

The formation of the test pattern TEG including the process control marks and the alignment marks in the margin area BA enables, for example, checking whether an exposure mask has been placed at a correct position during the manufacturing processes of the display panel PNL by using a vernier that is one of the process control marks. Formation of the test pattern TEG including the process control marks and the alignment marks in the margin area BA further enables, for example, checking whether elements constituting the display elements are normally formed by using identification characters that are one of the process control marks. Furthermore, formation of the test pattern TEG including the process control marks and the alignment marks in the margin area BA enables, for example, alignment of various elements by using the alignment marks.

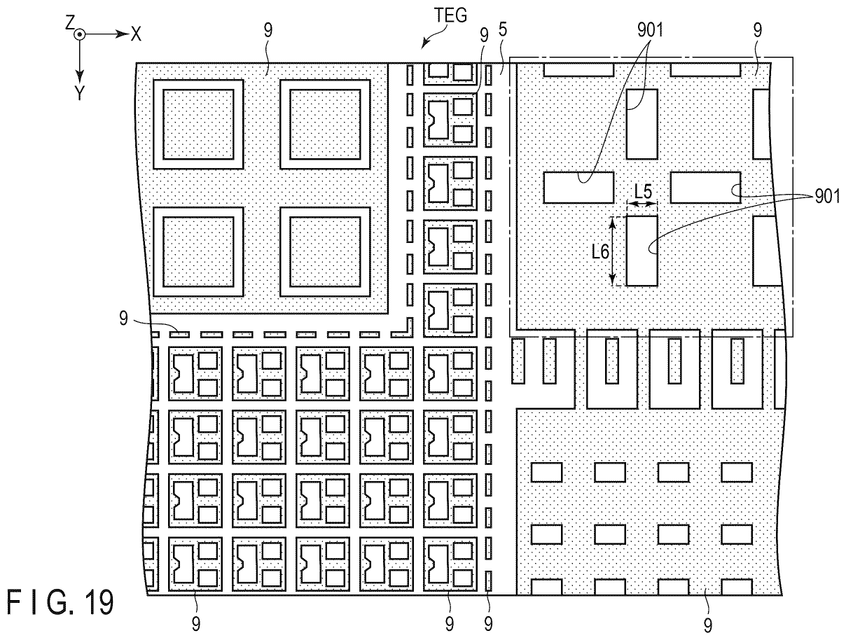

Unlike FIG. 8, FIG. 9, FIG. 14, and FIG. 15, FIG. 19 is a schematic plan view showing an example of a configuration applicable to the test pattern TEG (refer to the part surrounded by one-dot chain lines in the figure) for measuring cathode resistance, for example.

As shown in FIG. 19, the test pattern TEG is constituted by the rib layer 5 and a partition 9 (the second partition).

The rib layer 5 is provided across the panel portions PP and the margin area BA shown in FIG. 4.

Each partition 9 has a plurality of partition apertures 901 (recessed portions). A length in the X-direction of each partition aperture 901 is defined as a length L5 and a length in the Y-direction is defined as a length L6. The lengths L5 and L6 are preferably 40 μm to 50 μm or more.

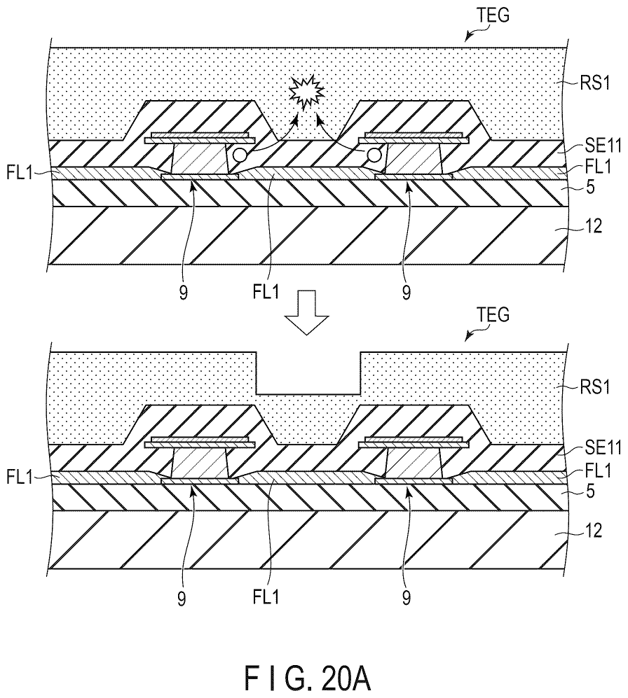

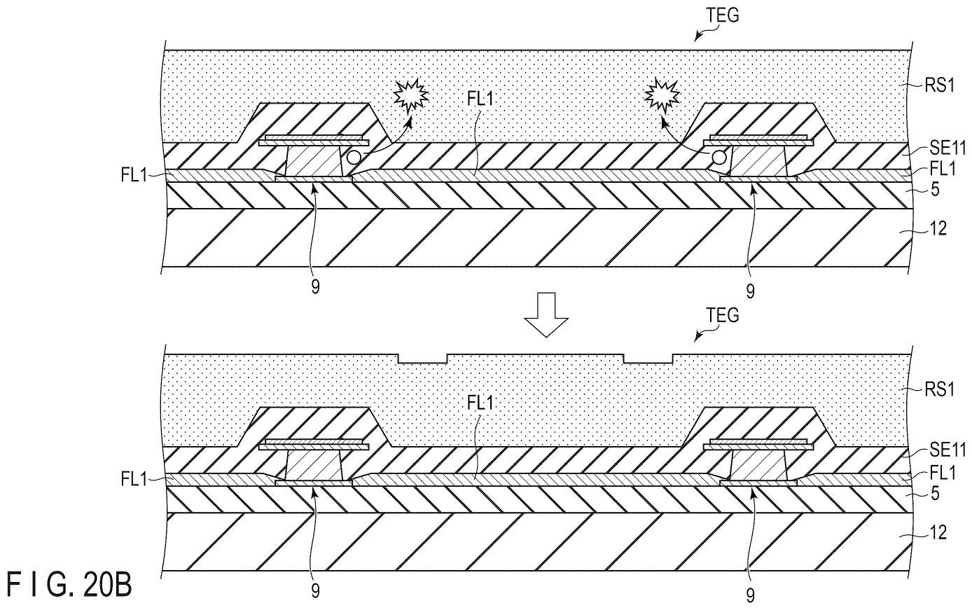

Unlike the test pattern TEG on which the process control marks and the alignment marks are formed, the test pattern TEG shown in FIG. 19 for measuring cathode resistance includes not only the stacked films FL1, FL2, and FL3 and the sealing layers SE11, SE12, and SE13 but also the resin layer RS1 provided on the sealing layers SE11, SE12, and SE13. In the test pattern TEG in which the resin layer RS1 is provided, the apertures 901 that has a small size results in the resin layer RS1 being divided and coating voids occurring when bubbles accumulated under an overhang of the overhang-shaped partition 9 escape as shown in FIG. 20A. In the test pattern TEG shown in FIG. 19 in which the resin layer RS1 is provided, formation of the partition apertures 901 having a predetermined size or larger, and more specifically, formation of the partition apertures 901 in which both the lengths L5 and L6 are 40 μm to 50 μm or more, is preferable, instead of mere formation of partition apertures. As shown in FIG. 20B, this configuration can prevent the resin layer RS1 from being divided and coating voids from occurring when bubbles accumulated under an overhang of the overhang-shaped partition 9 escape. Thus, this configuration enables normal formation of the test pattern TEG for measuring cathode resistance.

The test pattern TEG for measuring cathode resistance has the same advantageous points as the test pattern TEG on which process control marks and alignment marks are formed. That is, in the test pattern TEG for measuring cathode resistance as well, strong adhesion of the sealing layers SE11, SE12, and SE13 provided in the partition apertures 901 and therearound to the partition 9 (the side surfaces of the partition 9) is achieved by the placement of the partition 9 having the partition apertures 901 in the margin area BA and also the formation of the test pattern TEG in the margin area BA is achieved by letting the stacked films FL1, FL2, and FL3 provided in the partition apertures 901 and the sealing layers SE11, SE12, and SE13 provided on the partition apertures 901 and on the partition 9 around the partition apertures 901 remain.

As described above, embodiments enable efficient and highly accurate inspection during manufacture of the display device DSP. Various desirable effects can be obtained from the embodiment in addition to the effects explained here.

All of the display devices, the mother substrates, and manufacturing methods thereof that can be implemented by a person of ordinary skill in the art through arbitrary design changes to the display devices, the mother substrates, and manufacturing methods thereof disclosed above as each embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A mother substrate for a display device, comprising:
a plurality of panel portions each including a display area and a surrounding area around the display area;
a margin area around the plurality of panel portions;
a lower electrode provided in the display area;
a rib layer provided in the plurality of panel portions and the margin area;
a first partition provided in the display area;
a plurality of second partitions provided in the margin area;
a first stacked film provided in the plurality of panel portions and the margin area and including an organic layer of a first color; and
a first sealing layer covering the first stacked film, wherein
the plurality of second partitions are provided in a layout corresponding to a shape of a process control mark or an alignment mark, and
each of the process control mark and the alignment mark is constituted by a first stacked film provided on each of the plurality of second partitions and a first sealing layer covering the first stacked film and the plurality of second partitions.

2. The mother substrate of claim 1, wherein
the first sealing layer constituting the process control mark and the alignment mark adheres to side surfaces of the plurality of second partitions.

3. The mother substrate of claim 2, wherein
each of the first partition and the plurality of second partitions has a lower portion and an upper portion having an end portion protruding relative to a side surface of the lower portion, and
each of the first stacked film constituting the process control mark and the alignment mark is provided not near the side surfaces of the plurality of second partitions but on the upper portion of each of the plurality of second partitions.

4. The mother substrate of claim 3, wherein
the lower portion is provided on the rib layer in each of the first partition and the plurality of second partitions,
the lower portion included in each of the first partition and the plurality of second partitions is formed of the same material, and
the upper portion included in each of the first partition and the plurality of second partitions is formed of the same material.

5. The mother substrate of claim 1, wherein
the process control mark includes at least one of a vernier and an identification character for controlling a manufacturing process of the plurality of panel portions.

6. A mother substrate for a display device, comprising:
a plurality of panel portions each including a display area and a surrounding area around the display area;
a margin area around the plurality of panel portions;
a lower electrode provided in the display area;
a rib layer provided in the plurality of panel portions and the margin area;
a first partition provided in the display area;
a second partition provided in the margin area;
a first stacked film provided in the plurality of panel portions and the margin area and including an organic layer of a first color; and
a first sealing layer covering the first stacked film, wherein
the second partition has outer shape corresponding to a shape of a process control mark or an alignment mark and has a plurality of partition apertures, and
each of the process control mark and the alignment mark is constituted by a first stacked film provided on each of the plurality of partition apertures and a first sealing layer provided to cover the plurality of partition apertures.

7. The mother substrate of claim 6, wherein
the first sealing layer constituting the process control mark and the alignment mark adheres to side surfaces of the plurality of second partitions in each of the plurality of partition apertures.

8. The mother substrate of claim 7, wherein
each of the first partition and the second partition has a lower portion and an upper portion having an end portion protruding relative to a side surface of the lower portion, and
the first sealing layer constituting the process control mark and the alignment mark is provided not on the upper portion of the second partition but on the rib layer in each of the plurality of partition apertures.

9. The mother substrate of claim 8, wherein
the lower portion is provided on the rib layer in each of the first partition and the second partition,
the lower portion included in each of the first partition and the second partition is formed of the same material, and
the upper portion included in each of the first partition and the second partition is formed of the same material.

10. The mother substrate of claim 6, wherein
the process control mark includes at least one of a vernier and an identification character for controlling a manufacturing process of the plurality of panel portions.

11. A mother substrate for a display device, comprising:
a plurality of panel portions each including a display area and a surrounding area around the display area;
a margin area around the plurality of panel portions;
a lower electrode provided in the display area;
a rib layer provided in the plurality of panel portions and the margin area;
a first partition provided in the display area;
a second partition provided in the margin area;
a first stacked film provided in the plurality of panel portions and the margin area and including an organic layer of a first color;
a first sealing layer covering the first stacked film; and
a first resin layer covering the first sealing layer, wherein
the second partition has a plurality of partition apertures, and
each of the plurality of partition apertures has a width of 40 μm or more.
